(19) United States
(12) Patent Application Publication
(10) Pub. No.: US 2025/0171925 A1
(43) Pub. Date: May 29, 2025

(54) SUPPORTING PLATE, MANUFACTURING METHOD THEREOF AND SUBSTRATE PROCESSING DEVICE HAVING THE SAME

(71) Applicant: SEMES CO., LTD., Cheonan-si (KR)

(72) Inventors: Jaeoh BANG, Seoul-si (KR); Seunghwan LEE, Cheonan-si (KR); Gilsoo EUN, Cheonan-si (KR); Sunwoon KIM, Cheonan-si (KR)

(73) Assignee: SEMES CO., LTD., Cheonan-si (KR)

(21) Appl. No.: 18/884,411

(22) Filed: Sep. 13, 2024

(30) Foreign Application Priority Data
Nov. 29, 2023 (KR) 10-2023-0169479

(51) Int. Cl. C25D 17/06; B23K 20/10; B23K 101/34; C25D 3/12; C25D 5/48; C25D 11/02

(52) U.S. Cl. CPC C25D 17/06; B23K 20/10; C25D 3/12; C25D 5/48; C25D 11/02; B23K 2101/35

(57) ABSTRACT

It is disclosed that a support plate configured to enable the flow of ions during electroless plating or electrolytic plating to allow surface treatment on an inner flow path, a method of manufacturing the support plate and a substrate processing device having the support plate. A support plate includes an upper plate, a lower plate, and a stopper member. The lower plate has a formed inner flow path, disposed to face the upper plate, and has a plurality of penetration holes formed corresponding to each of the inflection points of the inner flow path. The stopper member is inserted into the penetration hole in a state in which the upper plate and the lower plate are bonded to each other. Therefore, by forming a separate penetration hole in a structure in which coating or plating of the inner flow path is not possible, the flow of ions during electroless plating or electrolytic plating is possible and surface treatment is possible.

### CROSS-REFERENCE TO RELATED APPLICATIONS

This application claims priority under 35 U.S.C. § 119 to Korean Patent Application No. 10-2023-0169479, filed on Nov. 29, 2023 in the Korean Intellectual Property Office (KIPO), the contents of which are herein incorporated by reference in their entirety.

### BACKGROUND OF THE INVENTION

### Technical Field

Exemplary embodiments of the present invention relate to a support plate, a method of manufacturing the support plate, and a substrate processing device having the support plate. More particularly, exemplary embodiments of the present invention relate to a support plate configured to enable the flow of ions during electroless plating or electrolytic plating to allow surface treatment on an inner flow path, a method of manufacturing the support plate and a substrate processing device having the support plate.

### Discussion of the Related Art

In general, a semiconductor manufacturing process refers to forming a circuit by repeatedly depositing, heating, and cooling a photoresist on the upper surface of a wafer. An example of the semiconductor manufacturing process is as follows. First, an upper surface of the wafer for manufacturing the circuit is made through wafer cleaning and surface treatment. Subsequently, the photoresist is coated on the upper surface of the wafer and heated to a temperature of 150° C. or less to deposit the photoresist and cool the photoresist to room temperature of about 23° C. Subsequently, the circuit is deposited through etching, diffusion and development processes, and the circuit is formed by heating again to a high temperature of about 150° C. or higher. Subsequently, it goes through an etching process, and a metal material is inserted.

In the semiconductor manufacturing process, the photoresist may be deposited without changing properties to produce a semiconductor device having desired properties. Therefore, each and heating process is very important, and a cooling plate device is essentially used for this purpose.

The cooling plate is formed by brazing the cover plates to the flow path forming plate. Here, the flow path forming plate generally has an inner flow path groove that is open upward or downward, and the cover plate covers the flow path forming plate to close the inner flow path groove. Constant temperature water flows in the inner flow path groove, and thus, fitting corrosion occurs on the surface of the inner flow path of aluminum due to foreign materials or corrosive substances. In addition, there is a problem that leakage defects occur due to the corrosion of cracks caused by the underlying aluminum and the process.

### SUMMARY

Exemplary embodiments of the present invention provide a support plate configured to enable the flow of ions during electroless plating or electrolytic plating to allow surface treatment on an inner flow path, through a formation of separate penetration holes in structures where coating or plating of internal circuits is not possible.

Exemplary embodiments of the present invention also provide a substrate processing device equipped with the aforementioned support plate.

Exemplary embodiments of the present invention also provide a substrate processing device equipped with the aforementioned support plate. According to one aspect of the present invention, a support plate includes an upper

plate, a lower plate, and a stopper member. The lower plate has a formed inner flow path, disposed to face the upper plate, and has a plurality of penetration holes formed corresponding to each of the inflection points of the inner flow path. The stopper member is inserted into the penetration hole in a state in which the upper plate and the lower plate are bonded to each other.

In an exemplary embodiment of the present invention, a plating layer may be formed on the inner surface of the inner flow path.

In an exemplary embodiment of the present invention, the plating layer may include nickel-phosphorus (Ni—P).

In an exemplary embodiment of the present invention, a diameter of the penetration hole may be equal to or less than a width of the inter flow path.

In an exemplary embodiment of the present invention, the stopper member may be welded to the penetration hole by a laser.

In an exemplary embodiment of the present invention, the stopper member may be fused to the penetration hole by an ultrasonic welding method.

In an exemplary embodiment of the present invention, the stopper member may include a bolt.

According to another aspect of the present invention, there is provided a method of manufacturing a support plate. In the method, each of an upper plate and a lower plate is processed, respectively. The lower plate has a lower groove formed on an upper surface to form an inner flow path and a plurality of penetration holes formed in a region corresponding to each of the inflection points of the internal flow path among some regions of the lower groove. Then, a lower face of the upper plate and the upper face of the lower plate are blazed to form a support plate with internal spaces. Then, a first surface treatment of the internal space is performed through the penetration holes. Then, the penetration holes are filled through a stopper member. Then, a second surface treatment is performed on an outer surface of the support plate filled with the penetration holes by the stopper member.

In an exemplary embodiment of the present invention, an upper groove may be formed on the lower surface of the upper plate to correspond to the lower groove formed in the lower plate.

In an exemplary embodiment of the present invention the performing the first surface treatment may include Ni—P plating.

In an exemplary embodiment of the present invention, the performing the second surface treatment may include anodizing.

According to still another aspect of the present invention, there is provided a method of manufacturing a support plate. In the method, each of an upper plate and a lower plate are processed, respectively. The lower plate has a lower groove formed on an upper surface to form an inner flow path. Then, a lower face of the upper plate and the upper face of the lower plate are blazed to form a support plate with internal spaces. Then, a plurality of penetration holes is formed in a partial region of the lower groove formed in the lower plate of the support plate, which corresponds to each of the inflection points of the inner flow path. Then, a first surface treatment of the internal space through the penetration holes is performed. Then, the penetration holes are filled through a stopper member. Then, a second surface treatment on an outer surface of the support plate filled with the penetration holes by the stopper member is performed.

In an exemplary embodiment of the present invention, an upper groove may be formed on the lower surface of the upper plate to correspond to the lower groove formed in the lower plate.

In an exemplary embodiment of the present invention, the performing the first surface treatment may include Ni—P plating.

In an exemplary embodiment of the present invention, the performing the second surface treatment may include anodizing.

According to still another aspect of the present invention, a substrate processing device includes an index module, a processing module, and a plurality of buffer modules. The index module transfers a substrate from a container accommodating the substrate and receives a processed substrate back into the container. The processing module performs coating process and developing process on the substrate, receives the substrate accommodated in the container from the index module, and performs a substrate processing process. The buffer modules are partially disposed between the index module and the processing module. The buffer module comprises a frame having a rectangular parallelepiped shape with an empty inside, and a buffer unit disposed inside the frame to temporarily store the substrate during a process of processing the substrate. The buffer unit comprises a housing having an empty space therein, a support plate on which the substrate is disposed, and a connection block positioned between the support plates and fixedly coupled to the support plates. Each of the support plates comprises an upper plate, a lower plate, and a stopper member. The lower plate has a formed inner flow path, disposed to face the upper plate, and has a plurality of penetration holes formed corresponding to each of the inflection points of the inner flow path. The stopper member is inserted into the penetration hole in a state in which the upper plate and the lower plate are bonded to each other.

In an exemplary embodiment of the present invention, a plating layer may be formed on the inner surface of the inner flow path.

In an exemplary embodiment of the present invention, a diameter of the penetration hole may be equal to or less than a width of the inter flow path.

In an exemplary embodiment of the present invention, the stopper member may be formed by a laser or an ultrasonic welding method.

In an exemplary embodiment of the present invention, the stopper member may include a bolt.

According to the support plate, the method of manufacturing the support plate, and the substrate processing device having the support plate, by forming a separate penetration hole in a structure in which coating or plating of the inner flow path is not possible, the flow of ions during electroless plating or electrolytic plating is possible and surface treatment is possible.

### BRIEF DESCRIPTION OF THE DRAWINGS

The above and other features and aspects of the present invention will become more apparent by describing in detailed exemplary embodiments thereof with reference to the accompanying drawings, in which:

FIG. 1 is a perspective view schematically showing a substrate processing device according to one exemplary embodiment of the present invention;

FIG. 2 is a cross-sectional view of the substrate processing device showing a coating block or a developing block shown in FIG. 1;

FIG. 3 is a plan view of the substrate processing device shown in FIG. 1;

FIG. 4 is a perspective view illustrating an example of a buffer module shown in FIG. 1;

FIG. 5 is a perspective view illustrating a buffer unit of the buffer module shown in FIG. 4;

FIG. 6 is a plan view illustrating the support plate of the buffer unit shown in FIG. 5;

FIG. 7A is a cross-sectional view taken along the line I-I′ of the support plate shown in FIG. 6, and FIG. 7B is a cross-sectional view taken along the line II-II′ of the support plate shown in FIG. 6;

FIGS. 8A through 8E are cross-sectional views illustrating one example of the manufacturing method of the support plate shown in FIG. 6; and

FIGS. 9A through 9F are cross-sectional views illustrating another example of the manufacturing method of the support plate shown in FIG. 6.

### DETAILED DESCRIPTION OF THE INVENTION

The present invention is described more fully hereinafter with reference to the accompanying drawings, in which exemplary embodiments of the present invention are shown. The present invention may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation shown in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-sectional illustrations that are schematic illustrations of idealized exemplary embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

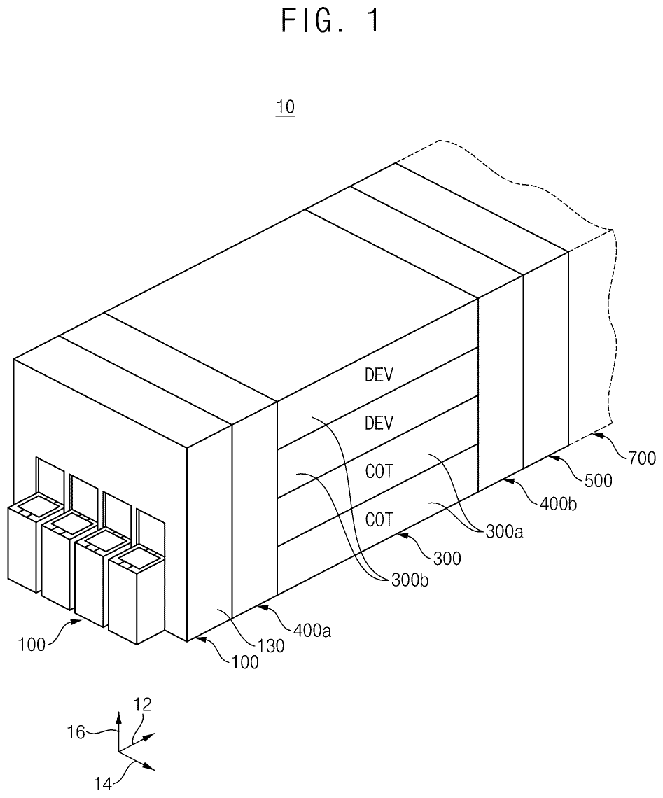

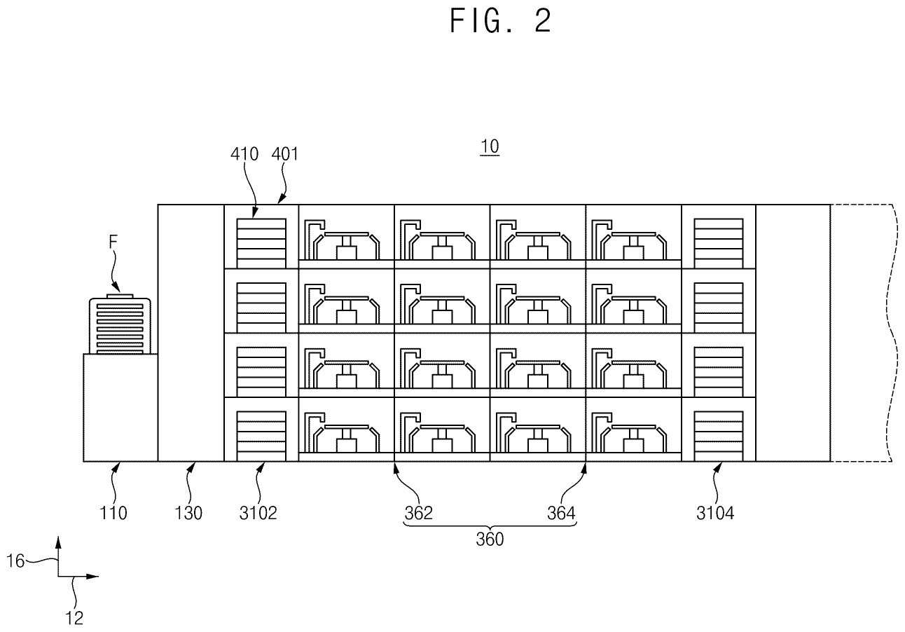

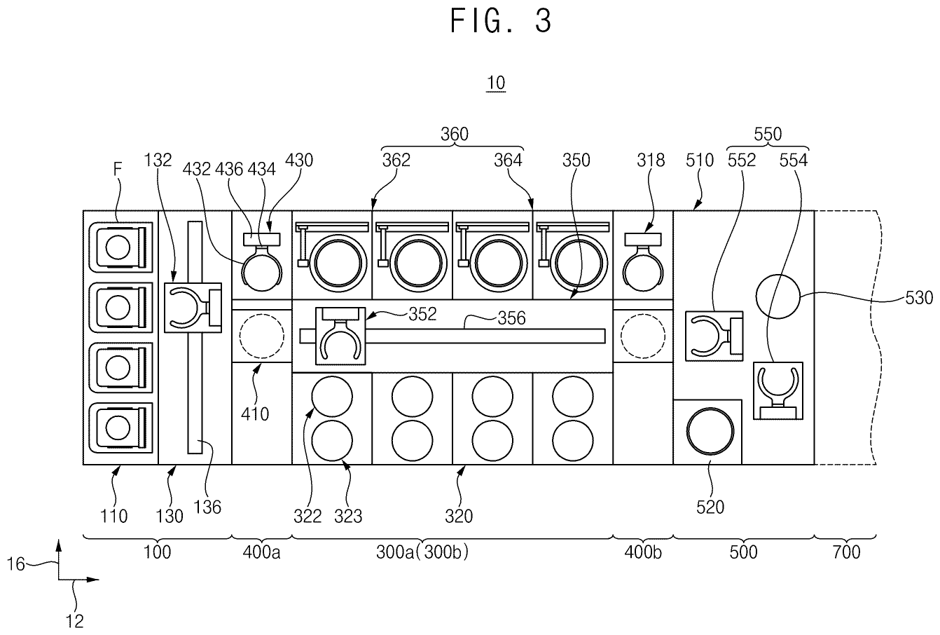

FIG. 1 is a perspective view schematically showing a substrate processing device according to an exemplary embodiment of the present invention. FIG. 2 is a cross-sectional view of the substrate processing device showing a coating block or a developing block shown in FIG. 1. FIG. 3 is a plan view of the substrate processing device shown in FIG. 1.

Referring to FIG. 1 through FIG. 3, the substrate processing device 10 according to an exemplary embodiment of the present invention includes an index module 100, a processing module 300, buffer modules 400a and 400b, and an interface module 500. Hereinafter, a direction in which the index module 100, the processing module 300, the buffer modules 400a and 400b, and the interface module 500 are arranged is defines as a first direction 12. A direction perpendicular to the first direction 12 when viewed from the top is defined as a second direction 14. A direction perpendicular to both the first direction 12 and the second direction 14 is defined as a third direction 16.

The index module 100 transfers the substrate W from the container F in which the substrate W is received to the processing module 300, and receives the processed substrate W to the container F. The longitudinal direction of the index module 100 is provided in a second direction 14. The index module 100 includes a load port 110 and an index frame 130. The load port 110 is disposed on the opposite side of the processing module 300 with respect to the index frame 130. The container F in which the substrates W are accommodated is placed in the load port 110. A plurality of load ports 110 may be provided, and a plurality of load ports 110 may be disposed along the second direction 14.

As the container F, a sealing container F such as a front open unified pod (FOUP) may be used. The container F may be placed in the load port 110 by a transfer means (not shown) such as an overhead transfer, an overhead conveyor, or an automatic guided vehicle (AGV), or an operator.

An index robot 132 is provided inside the index frame 130. In the index frame 130, a guide rail 136 having a length direction provided in a second direction 14 may be provided, and the index robot 132 may be provided to be movable on the guide rail 136. The index robot 132 includes a hand on which the substrate W is placed. The hand may be provided to be forward and backward moving, rotating about a third direction 16, and be movable along a third direction 16.

The processing module 300 may perform a coating process and a developing process on the substrate W. The processing module 300 may receive the substrate W accommodated in the container F to perform a substrate processing process. The processing module 300 has a plurality of coating blocks 300a and a plurality of developing blocks 300b. The plurality of coating blocks 300a perform a coating process on the substrate W, and the plurality of developing blocks 300b perform a developing process on the substrate W. The coating blocks 300a are provided to be stacked on each other. The developing blocks 300b are provided to be stacked on each other. According to an exemplary embodiment of FIG. 1, two coating blocks 300a and two developing blocks 300b are provided, respectively. The coating blocks 300a may be disposed under the developing blocks 300b. According to an exemplary embodiment, two coating blocks 300a may perform the same process and may be provided in the same structure. In addition, two developing blocks 300b may perform the same process and may be provided in the same structure.

Referring to FIG. 3, the coating block 300a includes a heat treatment chamber 320, a transfer chamber 350 and a liquid treatment chamber 360. The heat treatment chamber 320 performs a heat treatment process on the substrate W. The heat treatment process may include a cooling process and a heating process. The liquid treatment chamber 360 forms a liquid film by supplying a liquid onto the substrate W. The liquid film may be a photoresist film or an antireflection film. The transfer chamber 350 transfers the substrate W between the heat treatment chamber 320 and the liquid treatment chamber 360 in the coating block 300a.

The transfer chamber 350 is provided with a longitudinal direction parallel to the first direction 12. A transfer robot 352 is provided in the transfer chamber 350. The transfer robot 352 conveys a substrate between the heat treatment chamber 320, the liquid treatment chamber 360, and the buffer module 400. According to an exemplary embodiment, the transfer robot 352 has a hand on which the substrate W is placed. The hand may be provided to be forward and backward moving, rotating about a third direction 16, and movable along a third direction 16. A guide rail 356 having a longitudinal direction parallel to the first direction 12 is provided in the transfer chamber 350, and the transfer robot 352 may be provided to be movable on the guide rail 356.

A plurality of buffer modules 400a and 400b are provided. Some of these buffer modules 400a and 400b are disposed between the index module 100 and the processing module 300. Hereinafter, the buffer modules 400a and 400b are referred to as front end buffers 400a. A plurality of front end buffers 400a is provided, and is positioned to be stacked on each other in the vertical direction. Other buffer modules 400a and 400b are disposed between the processing module 300 and the interface module 500. Hereinafter, these buffer modules 400a and 400b are referred to as rear buffers 400b. A plurality of rear-end buffers 400b are provided, and are positioned to be stacked on each other in the vertical direction. Each of the front end buffers 400a and the rear end buffers 400b temporarily stores a plurality of substrates W. The substrate W stored in the front end buffer 400a is transferred in or out by the index robot 132 and the transfer robot 352. The substrate W stored in the rear buffer is transferred in or out by the transfer robot 352 and the first robot 552.

Hereinafter, the buffer modules 400a and 400b will be described with reference to the front end buffer 400a.

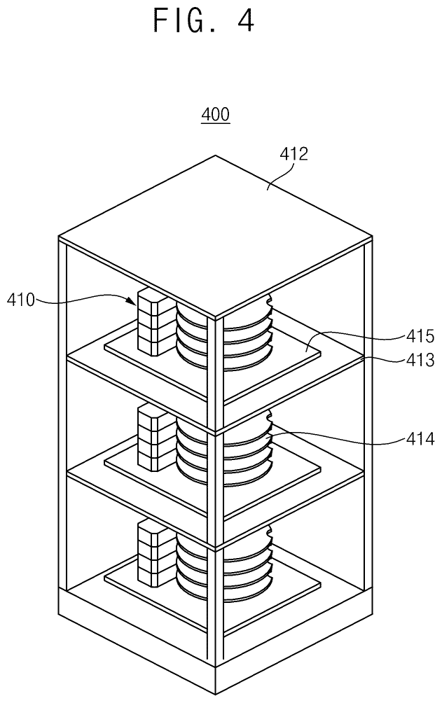

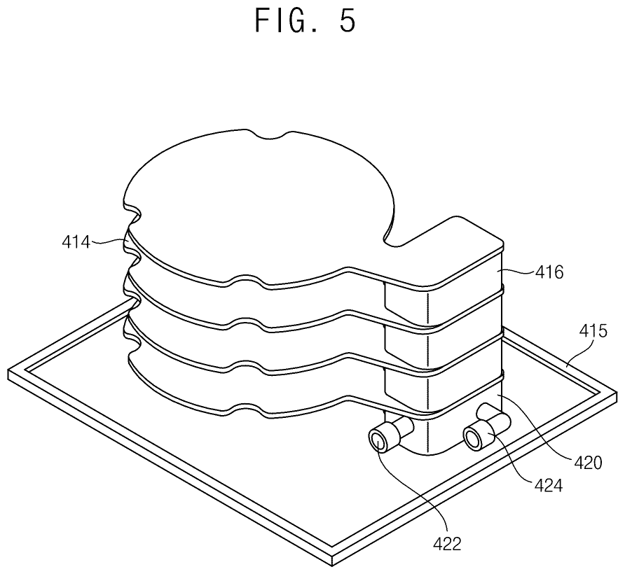

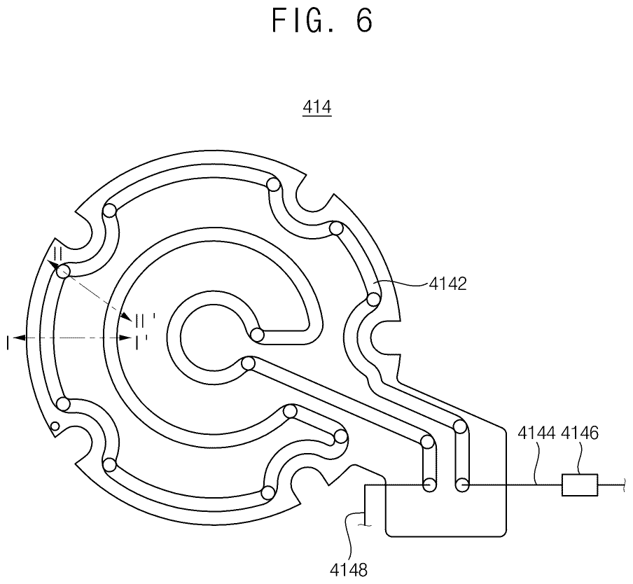

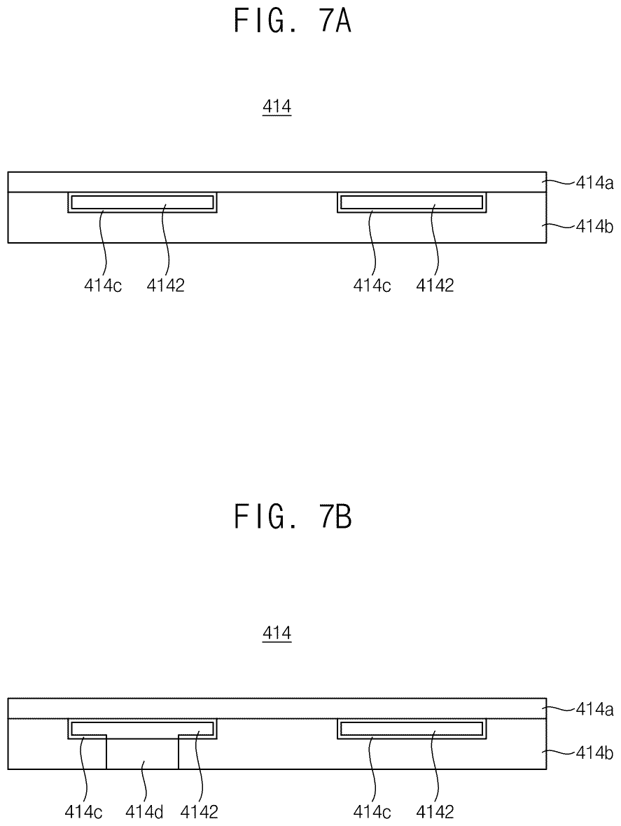

FIG. 4 is a perspective view illustrating an example of a buffer module shown in FIG. 1. FIG. 5 is a perspective view illustrating a buffer unit of the buffer module shown in FIG. 4. FIG. 6 is a plan view illustrating the support plate of the buffer unit shown in FIG. 5. FIG. 7A is a cross-sectional view taken along the line I-I′ of the support plate shown in FIG. 6, and FIG. 7B is a cross-sectional view taken along the line II-II′ of the support plate shown in FIG. 6.

Referring to FIG. 4 through FIG. 7B, the buffer module 400 includes a frame 401, a buffer unit 410 and a buffer robot 430.

The frame 401 may be provided in a rectangular parallelepiped shape having an empty inside. The frame 401 is disposed between the index module 100 and the liquid treatment chamber 360. The frame 401 is provided with a buffer unit 410 and a buffer robot 430 therein.

The buffer unit 410 temporarily stores the substrate W during the process of processing the substrate W. The buffer unit 410 may be provided in a structure of cooling the substrate W. The buffer unit 410 includes a housing 412, a support plate 414 and a connection block 416.

The housing 412 has an empty space therein. The housing 412 generally has a rectangle shape. The housing 412 is disposed in the frame 401 of the buffer module 400a. The housing 412 is disposed between the index module 100 and the processing module 300. A side portion of the housing 412 is opened. As an example, two side surfaces of the housing 412 are opened. The open space of the housing 412 is provided as a passage through which the substrate W enters and exits. A pedestal 413 is provided inside the housing 412.

The pedestal 413 may be provided as a rectangular plate. A plurality of pedestal 413 may be provided. Each pedestal 413 is positioned vertically in parallel. A plurality of support plates 414 may be stacked and positioned on an upper portion of each pedestal 413. As an example, three pedestals 413 may be provided.

The substrate W is placed on the support plate 414. The support plate 414 is provided in a circular shape when viewed from the top. The support plate 414 may have a size corresponding to that of the substrate W.

In the above-described example, the buffer unit 410 is divided into three spaces inside the housing 412 and the support plate 414 is provided, but the number of spaces inside the housing may be provided differently.

A plurality of support plates 414 is provided. Each of the support plates 414 is disposed to be stacked in the vertical direction. The support plate 414 may be made of an aluminum material. A connection block 416 is positioned between the support plates 414. The support plates 414 are positioned to be spaced apart from each other by the connection block 416. Each of the support plates 414 is fixedly coupled to the connection block 416. Each of the support plates 414 may be provided in the same size. Each of the support plates 414 may be provided to be spaced apart from each other at the same height.

The support plate 414 has an inner flow path 4142 formed therein through which a constant temperature fluid flows. The constant temperature fluid may be provided as a coolant. A first end of the inner flow path 4142 is connected to a supply line 4144 that supplies the cryogenic fluid. The supply line 4144 is connected to a refrigerant source 4146. The other end of the inner flow path 4142 is connected to the discharge line 4148. Refrigerant source 4146 supplies a constant temperature fluid to inner flow path 4142. The cryogenic fluid supplied to the supply line 4144 flows in the inner passage 4142 and is discharged to the outside through the discharge line 4148. The cold heat from the cryogenic fluid flows along the inner flow path 4142 and lowers the temperature of the support plate 414. The support plate 414 exchanges heat with the substrate being placed on the support plate 414.

In this embodiment, the support plate 414 includes a bonded upper plate 414a, and a lower plate 414b. The upper plate 414a has a flat shape and is disposed on top of the lower plate 414b. A substrate may be disposed on top of the upper plate 414a. An inner channel 4142 is formed in the lower plate 414b and disposed facing the upper plate 414a. A plurality of penetration holes (not shown) are formed corresponding to each of the inflection points of the inner flow path 4142. The diameter of the penetration holes may be equal to or less than the width of the inner channel 4142. In this embodiment, the number of inflection points is 14, and therefore the number of penetration holes is also 14.

A plating layer 414c is formed on the inner surface of the inner flow path 4142. The plating layer 414c includes nickel-phosphorus (Ni—P). The plating layer 414c may be formed by an electroless plating method, or it may be formed by an electrolytic plating method. In this embodiment, the plating layer 414c can be formed by electroless nickel plating, which has better corrosion resistance than electrolytic nickel plating. In this embodiment, nickel and phosphorus are utilized to form the plating layer 414c, with a higher percentage of phosphorus resulting in fewer pinholes and improved corrosion resistance.

When the upper plate 414a and lower plate 414b are joined together, stopper member 414d is inserted into the penetration holes. In one example, the stopper member 414d may be welded into the penetration holes using laser welding. In another example, stopper member 414d may be fused into the penetration holes using ultrasonic bonding methods. In still another example, stopper member 414d may include bolts.

As described above, in the present invention, an inner flow path is formed in an aluminum plate and bonded by brazing to be used as a cooling substrate in the same manner as in the prior art. However, in the case of such a structure, surface treatment inside is not possible. Therefore, a penetration hole is formed in the position of the inner flow path on the lower surface (i.e., opposite to the wafer mounting surface), and a separate path is formed to enable electroless plating or electrolytic plating. As described above, according to the present invention, by forming a separate penetration hole in a structure in which coating or plating of the inner flow path is not possible, surface treatment is possible by enabling the flow of ions during electroless plating or electrolytic plating.

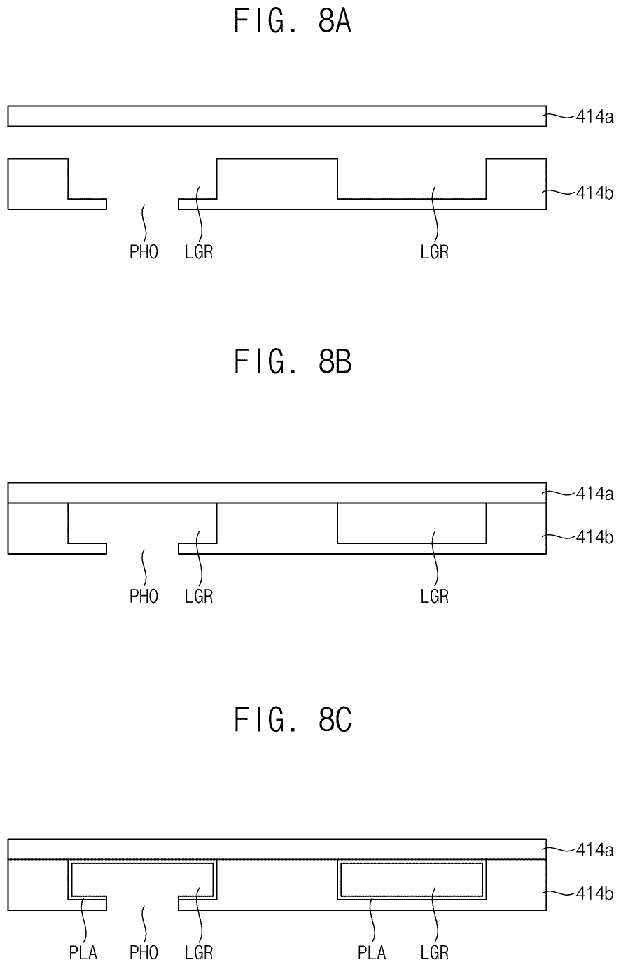

FIGS. 8A through 8E are cross-sectional views illustrating one example of the manufacturing method of the support plate shown in FIG. 6.

Referring to FIG. 8A, a shape of the upper plate 414a is processed. In addition, in order to form an inner flow path, a shape of the lower plate 414b having a lower groove LGR formed on an upper surface thereof and a plurality of penetration holes PHO formed in a region corresponding to each of an inflection points of the inner flow path is processed. In the drawings, a left lower groove represents a partial region of the inner flow path corresponding to an inflection point, and a right lower groove represents a partial region of the inner flow path that does not correspond to the inflection point. Here, an upper groove may be further formed on a lower surface of the upper plate 414a to form an inner flow path.

Then, as shown in FIG. 8b, the lower surface of the upper plate 414a and the upper surface of the lower plate 414b are blazed at a temperature of about 600 degrees Celsius to form a support plate having an internal space. Here, blazing is a method of melting a metal (e.g., filler metal) (not shown) having a melting point lower than that of the upper plate 414a or lower plate 414b without melting the upper plate 414a or the lower plate 414b as a base material at all and bonding it between the lower surface of the upper plate 414a and the upper surface of the lower plate 414b by suction force by surface tension.

Then, as shown in FIG. 8C, the plating layer PLA is formed by performing a first surface treatment with Ni—P plating in the inner space through the penetration hole PHO.

Then, as shown in FIG. 8D, a process of filling the penetration hole PHO through the stopper member SME is performed.

Then, as shown in FIG. 8E, an outer surface of the support plate filled with the penetration hole PHO by the stopper member SME is treated with a second surface treatment by an anodizing process to form a surface coating layer SCL. Here, the anodizing refers to a process of forming an oxide film on a metal surface. For example, the anodizing refers to a process of making a support plate an anode in an electrolyte and applying a voltage to form a film of aluminum oxide (Al₂O₃). A surface treatment process may also include a plasma electrolytic oxidation process.

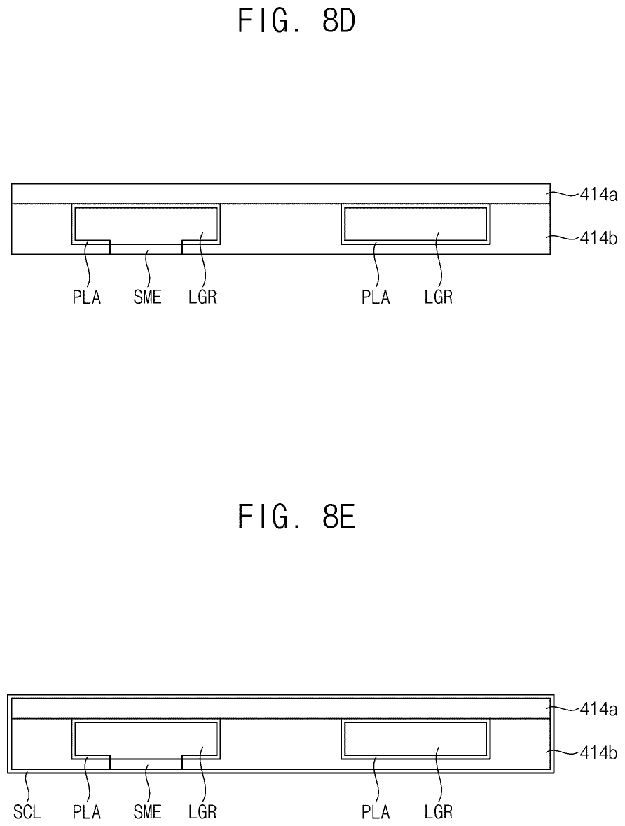

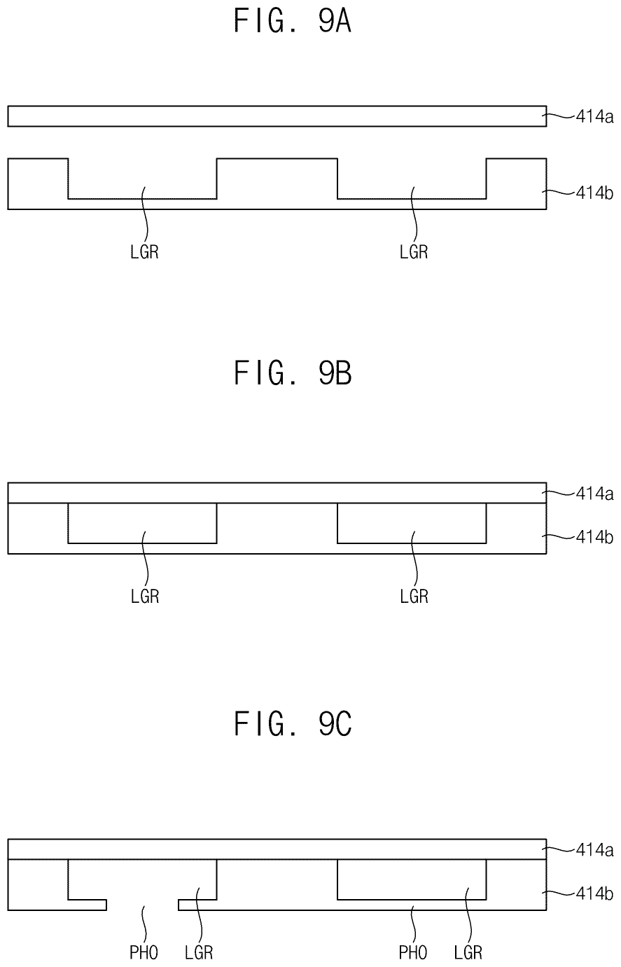

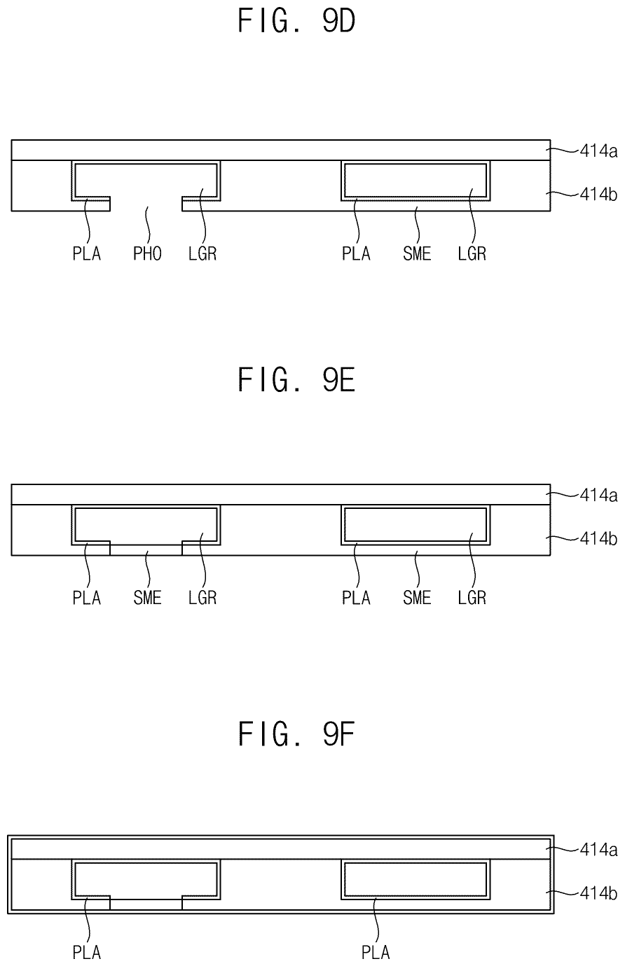

FIGS. 9A through 9F are cross-sectional views illustrating another example of the manufacturing method of the support plate shown in FIG. 6.

Referring to FIG. 9A, a shape of an upper plate 414a is processed. A shape of each of the lower plates 414b having a lower groove LGR formed on the upper surface thereof is processed to form an inner flow path facing the upper plate 414a. In FIG. 9A, a left lower groove represents a partial area of the inner flow path corresponding to an inflection point, and a right lower groove represents a partial area of the inner flow path that does not correspond to the inflection point. Here, an upper groove may be further formed on a lower surface of the upper plate 414a to form an inner flow path.

Then, as shown in FIG. 8b, the lower surface of the upper plate 414a and the upper surface of the lower plate 414b are blazed at a temperature of about 600 degrees Celsius to form a support plate having an internal space. Here, blazing is a method of melting a metal (e.g., filler metal) (not shown) having a melting point lower than that of the upper plate 414a or lower plate 414b without melting the upper plate 414a or the lower plate 414b as a base material at all and bonding it between the lower surface of the upper plate 414a and the upper surface of the lower plate 414b by suction force by surface tension.

Then, as shown in FIG. 9C, a plurality of penetration holes PHO are formed in a region corresponding to each of the inflection points of the internal flow path among some regions of the lower groove LGR formed in the lower plate 414b of the support plate.

Then, as shown in FIG. 9D, the plating layer PLA is formed by performing a first surface treatment with Ni—P plating in the inner space through the penetration hole PHO.

Then, as shown in FIG. 9E, a process of filling the penetration hole PHO through the stopper member SME is performed.

Lastly, as show in in FIG. 9F, an outer surface of the support plate filled with the penetration hole PHO by the stopper member SME is treated with a second surface treatment by an anodizing process to form a surface coating layer SCL. Here, the anodizing refers to a process of forming an oxide film on a metal surface. For example, the anodizing refers to a process of making a support plate an anode in an electrolyte and applying a voltage to form a film of aluminum oxide (Al₂O₃). A surface treatment process may also include a plasma electrolytic oxidation process.

As described above, according to the present invention, an inner flow path is formed on the aluminum plate and bonded by brazing to be used as a cooling substrate, but a penetration hole is formed as a separate path to enable electroless plating or electrolytic plating at the position of the inner flow path opposite to the wafer seating surface. As described above, by forming a separate penetration hole in a structure where coating or plating of an internal flow path is not possible, the flow of ions is possible during electroless plating or electrolytic plating, and surface treatment is possible. Thus, by forming a separate penetration hole in a structure in which coating or plating of the inner flow path is not possible, the flow of ions during electroless plating or electrolytic plating is possible and surface treatment is possible.

Having described exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A support plate comprising:
an upper plate;
a lower plate having a formed inner flow path, disposed to face the upper plate, and having a plurality of penetration holes formed corresponding to each of the inflection points of the inner flow path; and
a stopper member inserted into the penetration hole in a state in which the upper plate and the lower plate are bonded to each other.

2. The support plate of claim 1, wherein a plating layer is formed on the inner surface of the inner flow path.

3. The support plate of claim 2, wherein the plating layer includes nickel-phosphorus (Ni—P).

4. The support plate of claim 1, wherein a diameter of the penetration hole is equal to or less than a width of the inter flow path.

5. The support plate of claim 1, wherein the stopper member is welded to the penetration hole by a laser.

6. The support plate of claim 1, wherein the stopper member is fused to the penetration hole by an ultrasonic welding method.

7. The support plate of claim 1, wherein the stopper member comprises a bolt.

8. A method of manufacturing a support plate, the method comprising:
processing each of an upper plate and a lower plate, respectively, the lower plate having a lower groove formed on an upper surface to form an inner flow path and a plurality of penetration holes formed in a partial region of the lower groove corresponding to each of the inflection points of the inner flow path;
blazing a lower face of the upper plate and an upper face of the lower plate to form a support plate with an internal space;
performing a first surface treatment of the internal space through the penetration holes;
filling the penetration holes through a stopper member; and
performing a second surface treatment on an outer surface of the support plate filled with the penetration holes by the stopper member.

9. The method of claim 8, wherein an upper groove is formed on the lower surface of the upper plate to correspond to the lower groove formed in the lower plate.

10. The method of claim 8, wherein the performing the first surface treatment comprises Ni—P plating.

11. The method of claim 8, wherein the performing the second surface treatment comprises anodizing.

12. A substrate processing device comprising:
an index module transferring a substrate from a container accommodating the substrate and receiving a processed substrate back into the container;
a processing module performing coating process and developing process on the substrate, receiving the substrate accommodated in the container from the index module, and performing a substrate processing process; and
a plurality of buffer modules partially disposed between the index module and the processing module,
wherein the buffer module comprises: a frame having a rectangular parallelepiped shape with an empty inside, and a buffer unit disposed inside the frame to temporarily store the substrate during a process of processing the substrate,
wherein the buffer unit comprises a housing having an empty space therein, a support plate on which the substrate is disposed, and a connection block positioned between the support plates and fixedly coupled to the support plates,
wherein each of the support plates comprises:
an upper plate;
a lower plate having a formed inner flow path, disposed to face the upper plate, and having a plurality of penetration holes formed corresponding to each of the inflection points of the inner flow path; and
a stopper member inserted into the penetration hole in a state in which the upper plate and the lower plate are bonded to each other.

13. The substrate processing device of claim 12, wherein a plating layer is formed on the inner surface of the inner flow path.

14. The substrate processing device of claim 12, wherein a diameter of the penetration hole is equal to or less than a width of the inter flow path.

15. The substrate processing device of claim 12, wherein the stopper member is formed by a laser or an ultrasonic welding method.

16. The substrate processing device of claim 12, wherein the stopper member comprises a bolt.
